(19) United States
(12) Patent Application Publication
(10) Pub. No.: US 2023/0361538 A1
(43) Pub. Date: Nov. 9, 2023

(54) OPTOELECTRONIC DEVICE AND METHOD FOR PRODUCING SAME

(71) Applicant: ams-OSRAM International GmbH, Regensburg (DE)

(72) Inventors: Markus Horn, Ergoldsbach (DE); Joerg Erich Sorg, Regensburg (DE)

(73) Assignee: ams-OSRAM International GmbH, Regensburg (DE)

(21) Appl. No.: 18/246,791

(22) PCT Filed: Aug. 30, 2021
(86) PCT No.: PCT/EP2021/073913

§ 371 Date: Mar. 27, 2023

(30) Foreign Application Priority Data
Sep. 30, 2020 (DE) 10 2020 125 510.1

(51) Int. Cl. H01S 5/40; H01S 5/0234; H01S 5/026; H01S 5/0237; H01S 5/22

(52) U.S. Cl. CPC H01S 5/4043; H01S 5/0234; H01S 5/026; H01S 5/0237; H01S 5/22; H01S 5/4087

(57) ABSTRACT

The invention relates to an optoelectronic laser device which includes: a first set of edge-emitting laser diodes, the first set of edge-emitting laser diodes having one or more first laser diodes, each of which has a first light emission region for laser light on a side face, and a second set of edge-emitting laser diodes, the second set of edge-emitting laser diodes having one or more second laser diodes, each of which has a second laser emission region for laser light on a side face, wherein the side faces of the first and second laser diodes lie at least substantially in the same plane, wherein a particular second laser diode (21b, 21d, 21f) is allocated to a particular first laser diode, and wherein the light emission regions of the first and of the allocated second laser diode are arranged at a distance from each other which is smaller than 10 μm, preferably smaller than 5 μm, further preferably smaller than 3 μm, and even further preferably smaller than 2 μm.

### CROSS-REFERENCE TO RELATED APPLICATIONS

The present application is a national stage entry from International Application No. PCT/EP2021/073913, filed on Aug. 30, 2021, published as International Publication No. WO 2022/069128 A1 on Apr. 7, 2022, and claims the priority of German Patent Application No. 10 2020 125 510.1, filed Sep. 30, 2020, the disclosures of all of which are hereby incorporated by reference in their entireties.

### FIELD OF THE INVENTION

The present invention relates to an optoelectronic laser device and a method of manufacturing an optoelectronic laser device.

### BACKGROUND OF THE INVENTION

Laser-based technologies, for example in a display, are used for technological applications such as augmented or mixed reality. In particular, laser diodes are used as lasers, which are designed for a power range of more than mW up to 100 mW of emitted radiation power, for example. The power requirement depends in particular on the application.

When laser diodes are used as part of a display solution, it may be desirable for the laser light to have a high output if, for example, sunlight falls on the display or if images to be generated are particularly detailed. On the other hand, it is desirable for laser diodes to require a low threshold current above which the laser diodes can generate laser light. This can save energy and extend battery life when used in a battery-powered device.

The requirement to be able to provide a high possible laser power on the one hand and to need a low threshold current on the other hand cannot be met without further ado. Against this background, the present invention is based on the object of providing an optoelectronic device which can be operated as required in such a way that a high laser power can be achieved or a low threshold current is required. Furthermore, a manufacturing method for an improved optoelectronic device is to be disclosed.

The object is solved by a device having the features of claim 1 or by a device having the features of claim 12. The manufacturing method according to the invention is indicated by claim 16. Preferred embodiments and further embodiments of the invention are described in the dependent claims.

### SUMMARY OF THE INVENTION

In particular, the invention relates to an optoelectronic laser device having a first set of edge emitting laser diodes, the first set of laser diodes comprising at least one first edge emitting laser diode having a first light emitting region for laser light on a side surface, and a second set of edge emitting laser diodes, the second set of laser diodes comprising at least one second edge emitting laser diode having a second light emitting region for laser light on a side surface. The side surfaces of the first and second laser diodes lie at least substantially in the same plane. Furthermore, the light emitting regions of the first and second laser diodes are arranged at a distance from each other which is smaller than 10 μm, preferably smaller than 5 μm, more preferably smaller than 3 μm, even more preferably smaller than 2 μm.

Since the light emitting regions of the first and second laser diodes are located at a very small distance from each other, they ideally appear as one light spot. The observer thus perceives no or only a slight change in the position of the light emission, regardless of whether the first laser diode or the second laser diode is operated. The use of optics, such as beam combiners, which combine the light paths of the light emitted by the laser diodes onto one light spot can thus be avoided. Furthermore, the first laser diode and the second laser diode can be designed such that one of the laser diodes provides a high output power of the emitted laser light, while the other laser diode requires a relatively low threshold current. One or the other laser diode can then be operated as needed. For example, laser powers can range from 5 mW to 300 mW. In pulsed laser operation, pulse durations can be in the range of 1 ns to 5 ns, for example.

The first set of edge emitting laser diodes may also comprise a plurality of first laser diodes, and the second set of edge emitting laser diodes may also comprise a plurality of second laser diodes, with a respective second laser diode being associated with a respective first laser diode. In addition, the light emitting regions of each of the first and associated second laser diodes are spaced apart by said distance. Thus, pairs of laser diodes, each consisting of a first laser diode and an associated second laser diode, are located in the common plane of the light emitting regions and at a distance from each other which is smaller than 10 μm, preferably smaller than 5 μm, further preferably smaller than 3 μm, still further preferably smaller than 2 μm.

The at least one first and second laser diode can each have a resonator for generating laser light, with the resonator of the first laser diode having a different length than the resonator of the second laser diode. The different length resonators allow different threshold currents and different maximum output powers to be realized. The laser diode with the shorter resonator typically provides a lower maximum output power, but requires a lower threshold current to generate laser light. Conversely, the laser diode with the longer resonator requires a higher threshold current for laser activity. However, it can provide a higher maximum power of emitted laser light.

In particular, the resonators can be arranged in such a way that they extend parallel to one another as viewed in their longitudinal direction, and a respective lateral end of a resonator can lie on the side surface. The respective light emitting region of the first or second laser diode is located at an end of the respective resonator lying on the side surface.

Other parameters of the resonators of the first and second laser diodes can also be different, such as the cross-section of the resonators or a mirror coating provided at the ends of the resonators. This can also result in different operating parameters for the first and second laser diodes.

It may be provided that a first chip comprises the first set of laser diodes and a second chip comprises the second set of laser diodes, the chips being arranged one above the other as viewed in the height direction in such a way that the first light emitting region of the first laser diode and the second light emitting region of the associated second laser diode lie in the same plane and are superimposed as viewed along the height direction.

The two chips can, for example, be assembled on top of each other at a slight distance using a so-called chip-on-chip assembly. The resonators in both chips can be formed by a respective ridge in the semiconductor layer sequence of the respective chip.

The chips can be arranged one above the other, for example, in such a way that the resonators of the laser diodes on the chips lie one above the other at a slight distance and are aligned parallel to one another.

The chips can be permanently bonded together using a joining process, for example AuSn thin film soldering (AuSn for a gold-tin solder material). Alternatively, a compression bonding process, such as Au—Au compression bonding, can be used (Au for gold). The thin layer between the chips can also improve the optical decoupling of the resonators, which are located directly above one another at a slight distance.

According to one embodiment of the invention, the first laser diode may be formed in a layer sequence of semiconductor layers of the first set of laser diodes, the second laser diode may be formed in a layer sequence of semiconductor layers of the second set of laser diodes, and the layer sequence of the second set of laser diodes may be arranged above the layer sequence of the first set of laser diodes as seen in the height direction. In this way, a structure can be realized in which the light emitting surfaces of the first and second laser diodes are very close to each other when viewed in all three spatial directions.

Such an embodiment can be achieved by chip-on-chip assembly as described above. It is also possible to create or provide the mentioned layer sequences on two wafers. For example, before superimposing the two wafers, resonators or ridges of different lengths can be created by etching optical mirrors on the top of each wafer using different masks. A separation process can then be used to separate several devices according to the invention from the joined wafers.

The first light emitting region may be formed on the side surface of a first layer of the layer sequences of the first set of laser diodes, and the second light emitting region may be provided on the side surface of a second layer of the layer sequences of the second set of laser diodes. Each layer sequence may be generated or provided on a respective wafer.

The first light emitting region may be formed by the side surface of a ridge formed in the first layer, and the second light emitting region may be formed by the side surface of a ridge formed in the second layer. The ridges, which are also referred to as ridges, may serve as resonators and may be adapted to different lengths.

A metallization layer can be provided between the layers of the two light emitting regions. This allows optical decoupling to be achieved between the resonators formed by the webs.

The first light emitting region of the first laser diode can be arranged above the second light emitting region of the second laser diode, viewed along the height direction. The light emitting regions can be very close to each other and thus be perceived as a single light spot.

According to a further development of the invention, viewed in the height direction, at least one layer with a first doping, in particular a p-doping, in the layer sequence of the first set of laser diodes can lie above at least one layer with a second doping, in particular an n-doping. Conversely, viewed in the height direction, at least one layer with the second doping, in particular an n-doping, can lie in the layer sequence of the second set of laser diodes above at least one layer with the first doping, in particular a p-doping. A respective active region for light generation results between the differently doped layers.

Such a further development can be realized, for example, by a chip-on-chip assembly, which has already been described above.

For example, a first chip having a first laser diode and a longer resonator formed by a ridge may be arranged such that a p-doped region of the chip is at the top. A second chip with a second laser diode having a shorter resonator formed by means of a ridge can be arranged so that the p-doped region of the chip is at the bottom and opposes the p-doped region of the first chip, with the distance between the resonators of the two chips being closely tolerated. The resulting structure permits separate operation of the laser diodes, with one common p-doped side and two separate n-doped sides available for electrical contact.

Seen in the height direction, at least one layer of a joint or bonding material, such as AuSn or Au, can be provided between the layer sequence of the first set of laser diodes and the layer sequence of the second set of laser diodes.

Optical decoupling of the resonators can thus be achieved. Furthermore, a permanent connection between the layer sequences can be realized.

The first set of laser diodes may comprise a number of first edge emitting laser diodes, and the second set of laser diodes may also comprise the number of second laser diodes, wherein each first laser diode of the first set of laser diodes is associated with a second laser diode of the second set of laser diodes, wherein the light emitting regions of the first and associated second laser diodes are arranged at the distance from each other which is smaller than 10 μm, preferably smaller than 5 μm, more preferably smaller than 3 μm, still more preferably smaller than 2 μm. The first set of laser diodes and the second set of laser diodes may thus comprise one to N laser diodes, where N is a natural number greater than 1. A multichannel system can thus be easily implemented that requires a low threshold current or can provide high laser power depending on which laser diodes are operated.

The at least one first laser diode of the first set and the at least one second laser diode of the second set of laser diodes may each be individually operable. Thus, each laser diode may be operable independently of another laser diode.

It may be provided that two or more first laser diodes of the first set of laser diodes have slightly different emission wavelengths, for example at a distance of 1 to nm. Alternatively or additionally, it may be provided that two or more second laser diodes of the second set of laser diodes have slightly different emission wavelengths, for example at a distance of 1 to 5 nm. In this case, the respective spectral emission width can be small, for example in the range of less than 1 nm. This can provide, for example, a flying spot system architecture in which a combination of coherent light sources, in particular lasers, with diffractive optical structures for image generation is advantageously achieved. Since several lasers, each with a small spectral emission width and slightly different emission wavelengths (delta=1-5 nm), are provided and their emission points are spatially very close together, a laser with broadened spectral emission is virtually created. This effectively suppresses optical artifacts in particular.

The invention also relates to an optoelectronic laser device in which a first set of edge emitting laser diodes is provided, the first set of laser diodes comprising at least one first edge emitting laser diode having, at a side surface, a first light emitting region for laser light. The laser device further comprises a second set of edge emitting laser diodes, the second set of laser diodes having at least one second edge emitting laser diode having a second light emitting region for laser light at a side surface. The side surfaces of the first and second laser diodes lie at least substantially in the same plane, and the optoelectronic laser device further comprises a light guide device having a set of light guides, wherein the set of light guides comprises at least one light guide having a first light guide section whose optical input is located in front of the first light emitting region and wherein the light guide comprises a second light guide section, the optical input of which is arranged in front of the second light emitting region, and wherein the output of the first light guide section and the output of the second light guide section open into a common light guide section, which has an optical output at its end opposite to the input.

The one optical output results in a light spot for light from the first and second laser diodes. A further optical device is therefore not required to obtain a light spot for light from both laser diodes. It is not necessary in this case, but it can still be provided, that the light emitting regions of the first and second laser diodes are arranged at a distance from each other which is smaller than 10 μm, preferably smaller than 5 μm, further preferably smaller than 3 μm, still further preferably smaller than 2 μm.

Furthermore, the first laser diode and the second laser diode can in turn be designed, in particular by means of resonators of different lengths, so that one of the laser diodes can provide a high output power of the laser light emitted by it, while the other laser diode requires a relatively low threshold current. Depending on requirements, one or the other laser diode can then be operated.

The light guide device can be formed in one piece, in particular as a monolithic component.

The first set of laser diodes may comprise a plurality of first edge emitting laser diodes, and the second set of laser diodes may also comprise the plurality of second laser diodes, each first laser diode of the first set of laser diodes being associated with a second laser diode of the second set of laser diodes, and the set of optical light guides comprising the plurality of optical light guides, each optical light guide being associated with a pair of first laser diode and associated second laser diode.

The invention also relates to an electronic apparatus comprising at least one optoelectronic device according to the invention, wherein the apparatus comprises a display in which the at least one optoelectronic device is integrated and/or wherein the apparatus is battery powered.

The display can be any display, for example for use in mobile devices such as a smartphone.

The display may also be in the form of an spectacle lens, which may have refractive or diffractive structures for light extraction. Such spectacle lenses may also have holographic structures for direct light guidance and image formation on the retina. An optoelectronic device according to the invention may be arranged outside a spectacle lens, and the provided light may be coupled into the spectacle lens, for example laterally.

Therefore, the invention may also relate to glasses, in particular virtual reality or augmented reality glasses, comprising at least one spectacle lens with refractive or diffractive structures and at least one optoelectronic device according to the invention, wherein the light provided by the optoelectronic device can be coupled into the spectacle lens.

The invention also relates to a method for manufacturing an optoelectronic device comprising the steps:
Providing a first set of edge emitting laser diodes comprising at least one first edge emitting laser diode having a first light emitting region for laser light on a side surface,
providing a second set of edge emitting laser diodes comprising at least one second edge emitting laser diode having a second light emitting region for laser light on a side surface, and
arranging the first and second sets of laser diodes such that the side surfaces of the first and second laser diodes lie at least substantially in the same plane and the light emitting regions of the first and second laser diodes lie at a distance from each other which is less than 10 μm, preferably less than 5 μm, more preferably less than 3 μm, still more preferably less than 2 μm.

It may be provided that a first chip comprising the first set of laser diodes is provided and that a second chip comprising the second set of laser diodes is provided, wherein the chips—viewed in height direction—are arranged one above the other in such a way that the first light emitting region of the first laser diode and the second light emitting region of the second laser diode lie in the same plane and, viewed along the height direction, lie one above the other at said distance.

It may be provided that the first chip and the second chip are permanently bonded together by means of joining and/or by means of compression bonding.

It may be provided that the first set of laser diodes and the second set of laser diodes are fabricated on one wafer.

Features or advantages mentioned in connection with one embodiment may also apply to another embodiment of a device or method according to the invention, even if no explicit reference is made thereto.

### BRIEF DESCRIPTION OF THE DRAWING

Exemplary embodiments of the invention are described below in connection with the accompanying figures. They show, schematically in each case,

FIG. 1 a perspective view of an exemplary component for an optoelectronic device according to the invention,

FIG. 2 a perspective view of a variant of an optoelectronic device according to the invention,

FIG. 3 a side view of the device of FIG. 2,

FIG. 4 another side view of the device of FIG. 2 rotated by 90° compared to FIG. 3,

FIG. 5 a perspective view of an exemplary component for an optoelectronic device according to the invention,

FIG. 6 a perspective view of yet another variant of an optoelectronic device according to the invention,

FIG. 7 a top view of the device of FIG. 6,

FIG. 8 exemplary operating ranges of a respective laser diode with a long and a short resonator as a function of the power of the generated light over the electric current through the respective laser diode,

FIG. 9 exemplary operating ranges of a respective laser diode with a long, a medium-length and a short resonator as a function of the power of the generated light over the electric current through the respective laser diode,

FIG. 10 a side view of a wafer with etched facets,

FIG. 11 a side view of another wafer with etched facets,

FIG. 12 a side view of the interconnected wafers of FIGS. and 11,

FIG. 13 a variant of an optoelectronic device according to the invention separated from a wafer composite as shown in FIG. 12,

FIG. 14 a side, sectional view of yet another variant of an optoelectronic device according to the invention, and

FIG. 15 a circuit sketch for interconnecting two associated laser diodes according to some aspects of the proposed principle.

### DETAILED DESCRIPTION

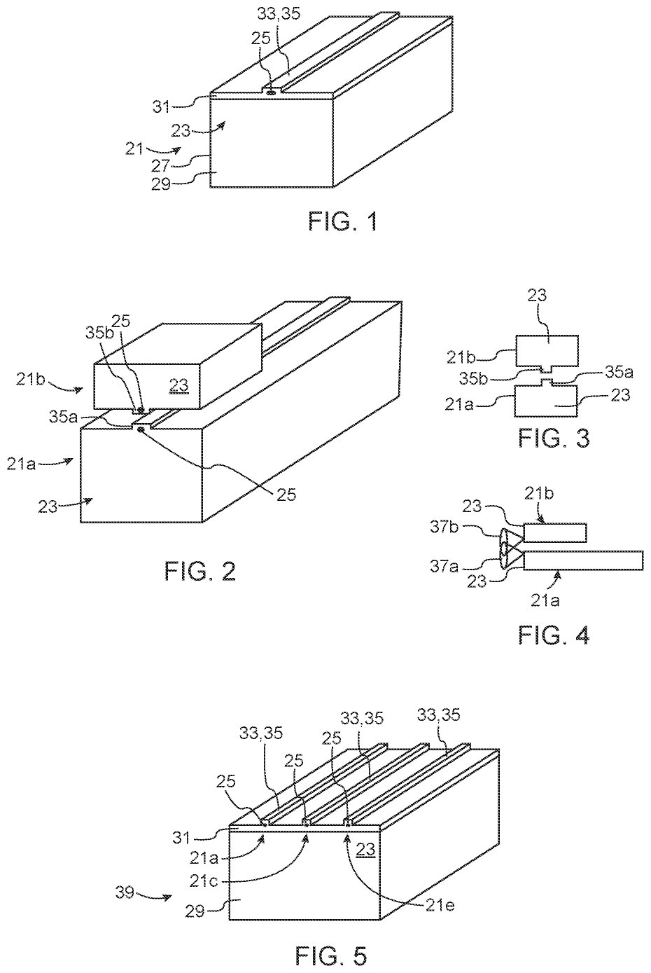

The component shown in FIG. 1 for an optoelectronic laser device according to the invention is an edge emitting laser diode 21, which has a light emitting region 25 for laser light on a side surface 23. The laser diode 21 is formed as a chip 27 and comprises an n-doped lower portion 29 and a p-doped upper portion 31 with an active region formed therebetween for light generation. The chip 27 has a ridge structure, with a ridge 33 serving as a resonator 35. The light emitting region 25 is therefore located in the area of the ridge 33 on the side surface 23 of the laser, which is located on the upper side of the chip 27. In contrast, the side surface at the rear, which is not visible, may be mirrored so that no laser light can emerge from this side surface.

The variant of an optoelectronic device according to the invention shown in FIGS. 2, 3 and 4 comprises a first laser diode 21a and a second laser diode 21b, each of which is designed like the laser diode 21 described with reference to FIG. 1. However, in the case of the laser diode 21a arranged at the bottom, the resonator 35a is longer than the resonator 35b of the laser diode 21b (cf. the different lengths of the laser diodes 21a, 21b according to FIG. 4). In addition, the second laser diode 21b is turned upside down so that its p-doped part 31 (cf. FIG. 1) faces downward, while the p-doped part 31 (cf. FIG. 1) of the first laser diode 21a faces upward. The structure permits separate operation of the first and second laser diodes 21a, 21b. In particular, common contacting of the p-doped parts 31 is possible, while separate contacting of the spatially separated n-doped parts can be performed. This allows the laser diodes 21a, 21b to be controlled or operated independently of one another.

The two laser diodes 21a and 21b are further arranged such that the resonators 35a and 35b are superimposed and parallel to each other, and the side surfaces 23 lie in a common plane. Furthermore, the light emitting regions 25 are located at a small distance from each other, which is smaller than 10 μm, preferably smaller than 5 μm, more preferably smaller than 3 μm, and even more preferably smaller than 2 μm. The light emitting regions are thus very close to each other. They can be perceived as a single light spot. Thus, the light emission can be perceived at least substantially in one light spot, regardless of whether the first or second laser diode 21a, 21b emits the light. This is illustrated in FIG. 4 by schematically shown light cones 37a, 37b, which are intended to represent a respective laser light emitted by the laser diode 21a, 21b.

The component shown in FIG. 5 for an optoelectronic device according to the invention corresponds to a multichannel laser diode chip 39 and has a structure based on the structure of the component of FIG. 1. In contrast to FIG. 1, the chip 39 has three ridges 33 extending parallel to each other, each of which serves as a resonator 35 of a laser diode 21a, 21c, 21e. The light emitting region 25 of each resonator 35 is again located in the area of the respective ridge 33 and on the side surface 23 of the chip 39. In contrast, the side surface of the chip 39 located at the rear, which is not visible, can be more strongly mirrored so that no laser light can emerge at the rear end of the respective ridge 33 or resonator 35.

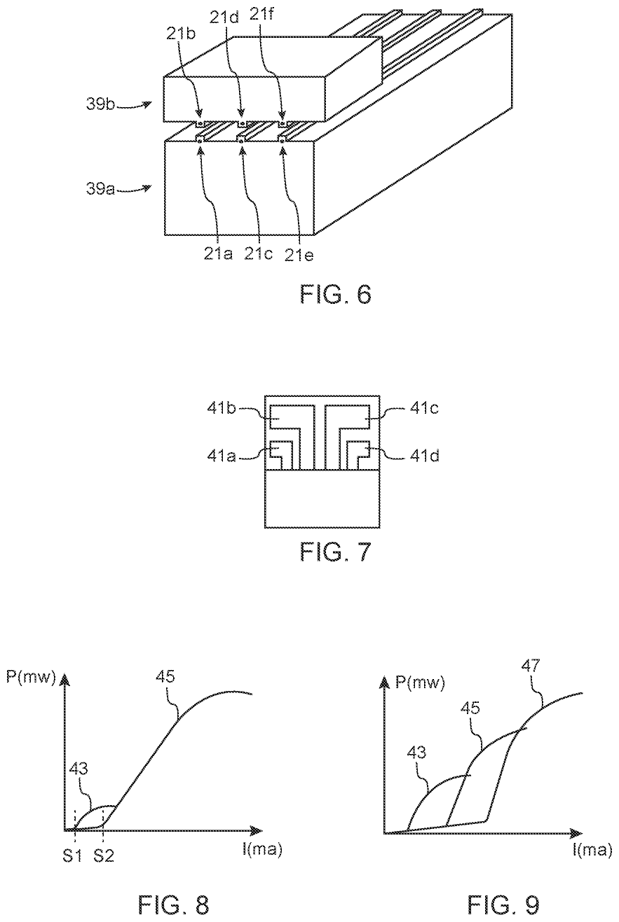

The variant of an optoelectronic device according to the invention shown in FIG. 6 comprises two multi-channel laser diode chips 39a and 39b, as described with reference to FIG. 5. In this case, the upper chip 39b is upside down so that a respective ridge of the laser diodes 21b, 21d and 21f of the upper chip 39b is located directly above a respective ridge of the laser diodes 21a, 21c and 21e. The laser diodes 21a and 21b, the laser diodes 21c and 21d, and the laser diodes 21e and 21f thereby form pairs of laser diodes whose light emitting region 25 lies in the same plane and which are arranged at a distance from one another which is smaller than 10 μm, preferably smaller than 5 μm, more preferably smaller than 3 μm, still more preferably smaller than 2 μm.

As further shown in FIG. 6, the upper chip 39b is formed shorter than the lower chip 39a, so that the resonators of the laser diodes 21b, 21d and 21f are shorter than the resonators of the laser diodes 21a, 21c and 21e on the lower chip 39.

In particular, the top view shown in FIG. 7 shows four contact areas 41a, 41b, 41c and 41d, also referred to as contact pads, which are used for electrically contacting the lasers 21b, 21d and 21f of the upper chip 39b of the device of FIG. 6. One of each of the contact pads 41a, 41c and 41d may be provided for contacting the n-doped portion of one of each of the laser diodes 21b, 21d and 21f. The three laser diodes 21b, 21d and 21f can be short-circuited at the p-doped part and connected to the contact area 41d. The laser diodes 21b, 21d and 21f of the upper chip 39b can be individually controlled or addressed via the contact areas 41a to 41d.

The diagram shown in FIG. 8 schematically represents the output power P in milliwatts (mW) of the laser light generated by a laser diode versus the current I through the laser diode in milliamperes (mA). In particular, the operating ranges of two laser diodes are schematically drawn in FIG. 8 as a characteristic curve reflecting the output power as a function of the current. The characteristic curve 43 refers to a laser diode with a short resonator (cf. for example the laser diode 21b in FIG. 2), while the characteristic curve 45 refers to a laser diode (cf. for example the laser diode 21a in FIG. 2) with a longer resonator.

As can be seen in FIG. 8, the laser diode with the shorter resonator according to characteristic curve 43 requires a low threshold current S1 for laser activity to start. On the other hand, the laser diode with the shorter resonator achieves a lower output power, here for example a maximum of about 10 mW, than the laser diode with the longer resonator, which here for example can provide a maximum of about 100 mW of output power (cf. characteristic curve 45). However, according to characteristic curve 45, the laser diode with the longer resonator requires a larger threshold current S2 at which laser activity begins.

In contrast to FIG. 8, FIG. 9 schematically shows another characteristic 47 of a further laser diode with an even longer resonator. This laser diode requires an even higher threshold current, but can also provide a higher maximum output power of laser light.

In the devices of FIGS. 2 and 6, the laser diodes of the upper chip 21b, 39b have a shorter resonator than the laser diodes of the lower chip 21a, 39a. Thus, according to FIGS. 8 and 9, they have a lower threshold current, while the laser diodes of the lower chip 21a, 39a can achieve a higher maximum output power. The light emitting regions 25 of the two laser diodes 21a, 21b of the device of FIG. 2 are at a slight distance apart. The same applies to the pairs of laser diodes 21a, 21b or 21c and 21d or 21e and 21f of the device of FIG. 6. The respective light spot of the laser diodes assigned to each other thus ideally appears as one light spot, regardless of which laser diode is operated. Depending on whether a high output power or a low threshold current is desired, one or the other laser diode of a laser diode pair can then be operated. The exemplary devices of FIGS. 2 and 6 according to the invention can thus meet both requirements—high power and low threshold current. The same requirements are also met by the variants described below.

The variants of FIGS. 2 and 6 described above were realized by arranging two chips with a respective set of laser diodes (comprising one or more laser diodes) one above the other. Thereby, the chips could be permanently arranged to each other via AuSn thin film soldering or Au—Au compression bonding, for example. A comparable device can also be created at wafer level, as described below.

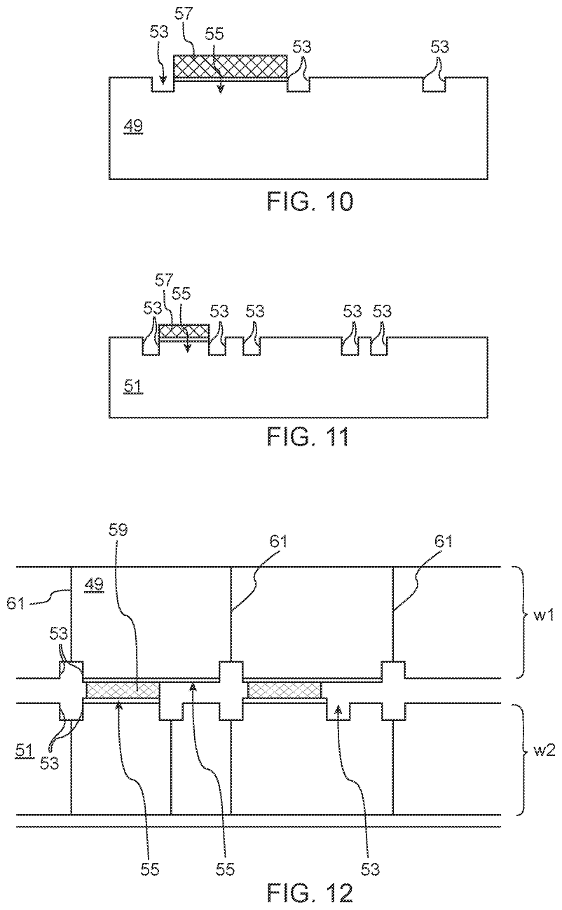

FIG. 10 shows a side view of a first wafer 49 and FIG. 11 shows a side view of another, second wafer 51. Each wafer 49, 51 has a layer structure known per se, which is required for the generation of a diode laser. Facets 53 are etched into each wafer 49, 51, between which a respective ridge or resonator comparable to the ridges and resonators 33, 35 of FIGS. 1 and 6 are defined on the upper surface of the wafer 49, 51. Shorter resonators 55 are formed on the wafer 51 of FIG. 11 than on the wafer 49 of FIG. 10. Furthermore, a metallization layer 57 can be applied over a respective resonator 55, which can be used, for example, to implement a common contact bond for the two wafers 49, 51.

FIG. 12 shows a side view of the interconnected wafers 49, 51 of FIGS. 10 and 11. The wafers 49, 51 are arranged one above the other in such a way that the resonators 55 of the two wafers 49, 51 run parallel to each other and face each other. In addition, the facets 53 located to the left of a respective pair of resonators 55 facing each other in FIG. 12 are arranged in a common plane.

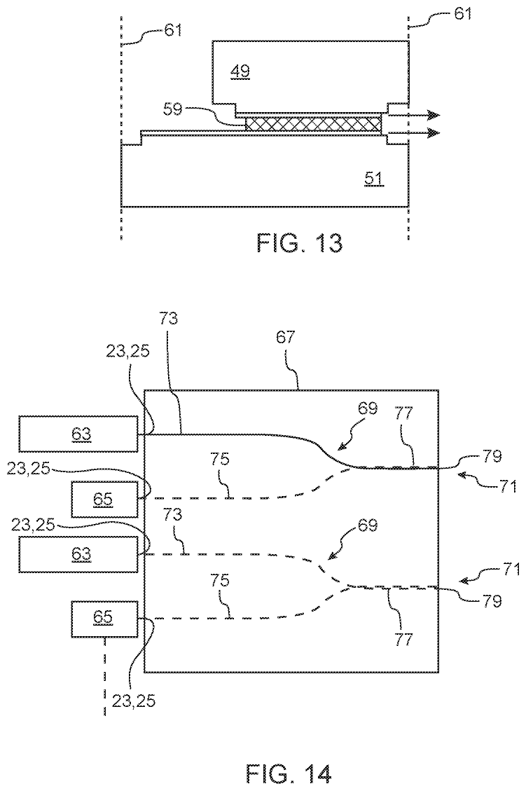

The two wafers 49, 51 are permanently bonded together via a joint 59, for example an Au—Au joint, which is produced by means of compression bonding. Separation can take place at separation points 61 shown in FIG. 12. This can produce a structure as shown in FIG. 13 and thus a variant of a device according to the invention.

The variant of an optoelectronic device according to the invention shown in FIG. 14 comprises a first set of edge-emitting first laser diodes 63. Each of the first laser diodes 63 has a light emitting region 25 for laser light on a side surface 23.

A second set of edge-emitting second laser diodes 65 is also provided, each of the second laser diodes 63 having a light emitting region 25 for laser light on a side surface 23. The side surfaces 23 of the laser diodes 63, 65 lie in the same plane, and a respective first laser diode 63 and second laser diode 65 form a pair.

The optoelectronic laser device further comprises an integrally formed light guide device 67 having a set of light guides 69. The set of light guides 69 comprises a plurality of light guides 71, each light guide 71 being associated with a pair of first and second laser diodes 65. Thus, the number of light guides 69 preferably corresponds to the number of pairs of laser diodes.

Each light guide 71 has a first light guide section 73, the optical input of which is arranged in front of the first light emitting region 25, and each light guide 71 has a second light guide section 75, the optical input of which is arranged in front of the second light emitting region 25. The optical output of the first light guide section 73 and the optical output of the second light guide section 75 open into a common light guide section 77, which forms an optical output 79 of the light guide 71 at its end opposite the input.

The one optical output 79 per light guide 71 results in a single point of illumination, regardless of which laser diode of the associated pair provides the light. An additional optical device is therefore not required to obtain a light spot for light from the two laser diodes of a laser diode pair.

It is not necessary, but it can still be provided, that the light emitting regions 25 of the laser diodes 63, 65 of a laser diode pair are arranged at a distance from each other which is smaller than 10 μm, preferably smaller than 5 μm, more preferably smaller than 3 μm, even more preferably smaller than 2 μm.

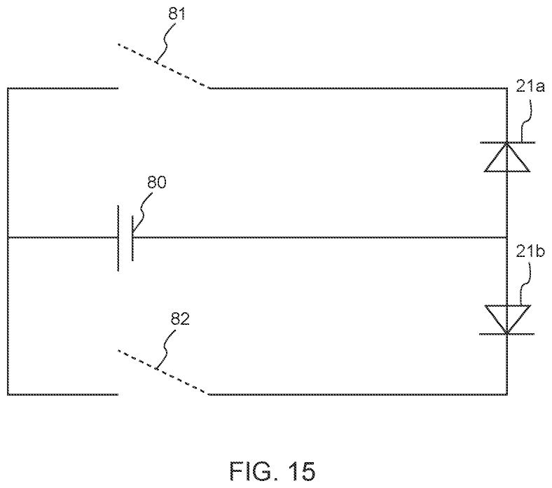

FIG. 15 shows a circuit sketch for interconnecting a first laser diode 21a and a second laser diode 21b associated with the first according to some aspects of the proposed principle. The laser diodes each comprise a resonator having a common first contact (p-contact) and separate second contacts (n-contact). As a result, the two resonators or laser diodes are individually controllable. The common first contact can be provided, for example, by forming a metallic, in particular electrically conductive, layer between the resonators. The common first contact of the laser diodes 21a, 21b is shown in the sketch in the form of a common electrical connection between the laser diodes 21a, 21b and a supply source 80, via which the laser diodes can be supplied with electrical energy. The separate second contacts of the laser diodes and thus the individual controllability of the laser diodes, on the other hand, is exemplarily sketched in the sketch in the form of the two switches 81, 82, via which the laser diodes can be electrically connected independently of one another.

1. An optoelectronic laser device comprising;
a first set of edge emitting laser diodes, the first set of edge emitting laser diodes comprising one or more first laser diodes each having a first light emitting region for laser light on a side surface,
a second set of edge emitting laser diodes, the second set of edge emitting laser diodes comprising one or more second laser diodes each having a second light emitting region for laser light on a side surface,
wherein the side surfaces of the first and second laser diodes lie at least substantially in the same plane,
wherein a respective second laser diode is associated with a respective first laser diode,
wherein the light emitting regions of the first and the associated second laser diode are arranged at a distance from each other which is smaller than 10 μm,
preferably smaller than 5 μm, more preferably smaller than 3 μm, still more preferably smaller than 2 μm, and
wherein the first and associated second laser diodes each have a resonator for generating laser light, the resonator of the first laser diode having a different length than the resonator of the associated second laser diode.

2. The optoelectronic device according to claim 1,
characterized in that
a first chip comprises the first set of laser diodes and a second chip (21b, 39b) comprises the second set of laser diodes, the two chips being arranged one above the other as seen in the height direction in such a manner that the first light emitting region of the first laser diode and the second light emitting region of the associated second laser diode lie in the same plane and are arranged one above the other as seen along the height direction.

3. The optoelectronic device according to claim 1,
characterized in that
the one or more first laser diodes are formed in a layer sequence of semiconductor layers of the first set of laser diodes,
the one or more second laser diodes are formed in a layer sequence of semiconductor layers of the second set of laser diodes, and
in that the layer sequence of the second set of laser diodes is arranged above the layer sequence of the first set of laser diodes, as seen in the height direction.

4. The optoelectronic device according to claim 3,
characterized in that
the first light emitting region is formed on the side surface of a first layer of the layer sequence of the first set of laser diodes and the second light emitting region is provided on the side surface of a second layer of the layer sequence of the second set of laser diodes.

5. The optoelectronic device according to claim 3,
characterized in that
the first light emitting region is formed by the side surface of a ridge formed in the first layer, and the second light emitting region is formed by the side surface of a ridge formed in the second layer.

6. The optoelectronic device according to claim 3,
characterized in that
the first light emitting region of the first laser diode is arranged above the second light emitting region of the associated second laser diode as viewed along the height direction.

7. The optoelectronic device according to claim 3,
characterized in that
seen in height direction, at least one layer with a first doping, in particular a p-doping, lies in the layer sequence of the first set of laser diodes above at least one layer with a second doping, in particular an n-doping, and, vice versa,
as seen in the height direction, at least one layer with the second doping, in particular an n-doping, lies in the layer sequence of the second set of laser diodes above at least one layer with the first doping, in particular a p-doping.

8. The optoelectronic device according to claim 3,
characterized in that
seen in height direction, at least one layer of a joint or bonding material, such as AuSn or Au, is provided between the layer sequence of the first set of laser diodes and the layer sequence of the second set of laser diodes.

9. The optoelectronic device according to claim 1,
characterized in that
the first set of laser diodes comprises a number of first edge emitting laser diodes, and the second set of laser diodes also comprises the number of second laser diodes, wherein a respective first laser diode of the first set of laser diodes is associated with a respective second laser diode of the second set of laser diodes, wherein the light emitting regions of the first and associated second laser diodes are arranged at a distance from each other which is smaller than 10 μm, preferably smaller than 5 μm, more preferably smaller than 3 μm, still more preferably smaller than 2 μm.

10. The optoelectronic device according to claim 1,
characterized in that
each laser diode of the first set of laser diodes and each laser diode of the second set of laser diodes is individually operable.

11. The optoelectronic device according to claim 1,
characterized in that
two or more first laser diodes of the first set of laser diodes have slightly different emission wavelengths, in particular at a distance of 1 nm to 5 nm, and/or
two or more second laser diodes of the second set of laser diodes have slightly different emission wavelengths, in particular at a distance of 1 nm to 5 nm.

12. An optoelectronic laser device comprising
a first set of edge emitting laser diodes, the first set of edge emitting laser diodes comprising one or more first laser diodes each having a first light emitting region for laser light on a side surface,
a second set of edge emitting laser diodes, the second set of edge emitting laser diodes comprising one or more second laser diodes each having a second light emitting region for laser light on a side surface,
wherein the side surfaces of the first and second laser diodes lie at least substantially in the same plane,
wherein a respective second laser diode is associated with a respective first laser diode,
wherein the first and associated second laser diodes each have a resonator for generating laser light, the resonator of the first laser diode having a different length than the resonator of the associated second laser diode, and
wherein further a light guide device is provided having a set of light guides, said set of light guides comprising at least one light guide having a first light guide section, the optical input of which is located in front of said first light emitting region, and having a second light guide section the optical input of which is arranged in front of the second light emitting region, and the output of the first light guide section and the output of the second light guide section opening into a common light guide section which has an optical output at its end opposite the input.

13. The optoelectronic device according to claim 12,
characterized in that
the light guide device is formed integrally, in particular as a monolithic component.

14. The optoelectronic device according to claim 12,
characterized in that
the first set of laser diodes comprises a number of first edge emitting laser diodes, and the second set of laser diodes also comprises the number of second laser diodes, wherein a respective first laser diode of the first set of laser diodes is associated with a respective second laser diode of the second set of laser diodes, and wherein the set of light guides also comprises the number of light guides, one light guide being associated with each pair of first laser diode and associated second laser diode.

15. An electronic apparatus comprising at least one optoelectronic device according to any claim 1,
wherein the apparatus comprises a display in which the at least one optoelectronic device is integrated and/or
wherein the apparatus is battery powered, and/or
wherein the apparatus is a pair of glasses, in particular virtual reality or augmented reality glasses, comprising at least one spectacle lens with refractive or diffractive structures and at least one optoelectronic device, wherein the light provided by the optoelectronic device can be coupled into the spectacle lens.

16. A method for manufacturing an optoelectronic device, in particular optoelectronic device according to claim 1, comprising:
providing a first set of edge emitting laser diodes comprising one or more first laser diodes having a first light emitting region for laser light on a side surface,
providing a second set of edge emitting laser diodes comprising one or more second laser diodes having a second light emitting region for laser light on a side surface,
arranging the first and second sets of laser diodes such that the side surfaces of the laser diodes of the two sets of laser diodes lie at least substantially in the same plane, such that a respective second laser diode of the second set of laser diodes is associated with a respective first laser diode of the first set of laser diodes, and such that the light emitting regions of the first and associated second laser diodes are at a distance from one another which is smaller than 10 μm, preferably smaller than 5 μm, more preferably smaller than 3 μm, still more preferably smaller than 2 μm, and
wherein the first and associated second laser diodes each have a resonator for generating laser light, the resonator of the first laser diode having a different length than the resonator of the associated second laser diode.

17. The method according to claim 16,
characterized in that
a first chip is provided comprising the first set of laser diodes, and that a second chip is provided comprising the second set of laser diodes,
wherein the chips are arranged one above the other as seen in the height direction in such a way that the first light emitting region of the first laser diode and the second light emitting region of the associated second laser diode lie in the same plane and are arranged one above the other as seen along the height direction.

18. The method according to claim 17,
characterized in that
the first chip and the second chip are permanently bonded to each other by means of joining and/or by means of compression bonding.

19. The method according to claim 16,
characterized in that
the first set of laser diodes and the second set of laser diodes are manufactured on a respective wafer.

20. The method according to claim 19,
characterized in that
the wafers are arranged and joined one above the other as seen in the height direction in such a way that the first light emitting region of the first laser diode and the second light emitting region of the associated second laser diode lie in the same plane and lie one above the other as seen along the height direction.

21. Use of an optoelectronic device according to claim 1 for suppressing artifacts, in particular in a flying spot architecture,
wherein in the optoelectronic device two or more first laser diodes of the first set of laser diodes have slightly different emission wavelengths, in particular at a distance of 1 nm to nm, and/or
wherein two or more second laser diodes of the second set of laser diodes have slightly different emission wavelengths, in particular at a distance of 1 nm to 5 nm.
